(19) United States
(12) Patent Application Publication
(10) Pub. No.: US 2007/0170950 A1
(43) Pub. Date: Jul. 26, 2007

(54) Plasma display panel and manufacturing method of plasma display panel

(75) Inventor: Yonghan Lee, Suwon (KR)

Correspondence Address: BIRCH STEWART KOLASCH & BIRCH, PO BOX 747, FALLS CHURCH, VA, 22040-0747, US

(73) Assignee: LG Electronics Inc.

(21) Appl. No.: 11/698,116

(22) Filed: Jan. 26, 2007

(30) Foreign Application Priority Data
Jan. 26, 2006 (KR) 10-2006-0008179

(51) Int. Cl. G01R 31/00

(52) U.S. Cl. 324/770

(57) ABSTRACT

A plasma display panel comprises a barrier rib, a substrate on which a scan electrode and a sustain electrode are displaced, a dielectric layer covering the scan electrode and the sustain electrode, a first protective layer covering the dielectric layer and a second protective layer covering the first protective layer, and having an area less than an area of the first protective layer.

This Nonprovisional application claims priority under 35 U.S.C. §119(a) on patent application Ser. No. 10-2006-0008179 filed in Korea on Jan. 26, 2006 the entire contents of which are hereby incorporated by reference.

### BACKGROUND

1. Field

This document is related to a plasma display panel and a manufacturing method of the plasma display panel.

2. Description of the Related Art

A plasma display panel comprises a front panel and a rear panel, and Discharge cells are between the front panel and the rear panel. Discharge gas comprising Xe and one of Ne, He and a mixture gas of Ne and He, is filled in the discharge cells. Pixels for displaying an image include the discharge cells. For example, one pixel includes a red discharge cell, a green discharge cell and a blue discharge cell.

When a discharge is generated in the plasma display panel, the discharge gas generates vacuum ultraviolet rays, vacuum ultraviolet rays excite a phosphor formed between barrier ribs, and then the phosphor emits light.

A driving voltage is supplied to an electrode of the plasma display panel. The driving voltage generates a reset discharge, an address discharge and a sustain discharge.

The plasma display panel includes a protective layer for facilitating a discharge condition. The protective layer is formed through a deposition of MgO. The protective layer emits electrons when the ions collide with the protective layer. An amount of the electrons is protportional to a secondary electron emission coefficient.

### SUMMARY

In one aspect, a plasma display panel comprises a barrier rib, a substrate on which a scan electrode and a sustain electrode are displaced, a dielectric layer covering the scan electrode and the sustain electrode, a first protective layer covering the dielectric layer and a second protective layer covering the first protective layer, and having an area less than an area of the first protective layer.

A region of the second protective layer may include at least one of a region corresponding to a gap between the scan electrode and the sustain electrode or a region corresponding to the barrier rib.

The first protective layer may include a dopant.

The first protective layer may include a dopant, and a concentration of the dopant may range from 100 ppm to 1000 ppm.

Each of the scan electrode and the sustain electrode may include a transparent electrode and a bus electrode, and a portion of the first protective layer may be positioned at a region corresponding to a gap between the transparent electrode of the scan eletrode and the transparent electrode of the sustain electrode.

A conductivity of the first protective layer may be greater than a conductivity of the second protective layer.

A thickness of the first protective layer may be greater than a thickness of the second protective layer.

A thickness of the second protective layer may range from 50 □ to 1000 □.

A thickness of the second protective layer may range from 50 □ to 100 □.

The first protective layer may include at least one of Si or Ti.

The first protective layer and the second protective layer may include MgO.

A secondary electron emission coefficient of the first protective layer may be greater than a secondary electron emission coefficient of the second protectiver layer.

In another aspect, a manufacturing method of a plasma display panel including a barrier rib, comprises forming a scan electrode and a sustain electrode on a substrate, forming a dielectric layer covering the scan electrode and the sustain electrode, forming a first protective layer on the dielectric layer, forming a second protective layer on the first protective layer and removing a portion of the second layer.

A region of the second protective layer may include at least one of a region corresponding to a gap between the scan electrode and the sustain electrode or a region corresponding to the barrier rib.

The first protective layer may include a dopant.

The first protective layer includes a dopant, and a concentration of the dopant ranges from 100 ppm to 1000 ppm.

Each of the scan electrode and the sustain electrode may include a transparent electrode and a bus electrode, and a portion of the first protective layer may be positioned at a region corresponding to a gap between the transparent electrode of the scan eletrode and the transparent electrode of the sustain electrode.

A conductivity of the first protective layer may be greater than a conductivity of the second protective layer.

A thickness of the first protective layer may be greater than a thickness of the second protective layer.

A thickness of the second protective layer may range from 50 □ to 1000 □.

A thickness of the second protective layer may range from 50 □ to 100 □.

The first protective layer may include at least one of Si or Ti.

A portion of the second protective layer may be removed by a supply of an aging pulse to the scan electrode and the sustain electrode alternately.

A secondary electron emission coefficient of the first protective layer may be greater than a secondary electron emission coefficient of the second protectiver layer.

### BRIEF DESCRIPTION OF THE DRAWINGS

The embodiment will be described in detail with reference to the following drawings in which like numerals refer to like elements.

FIG. 1 illustrates a plasma display panel according to an embodiment;

FIG. 2 illustrates a manufacturing process of the plasma display panel according to the embodiment;

FIG. 3 illustrates an emission of secondary electrons from a first protective layer and a second protective layer of the plasma display panel according to the embodiment.

FIG. 4 illustrates the first protective layer and the second protective layer of the plasma display panel according to the embodiment.

### DETAILED DESCRIPTION OF PREFERRED EMBODIMENTS

Embodiments will be described in a more detailed manner with reference to the drawings.

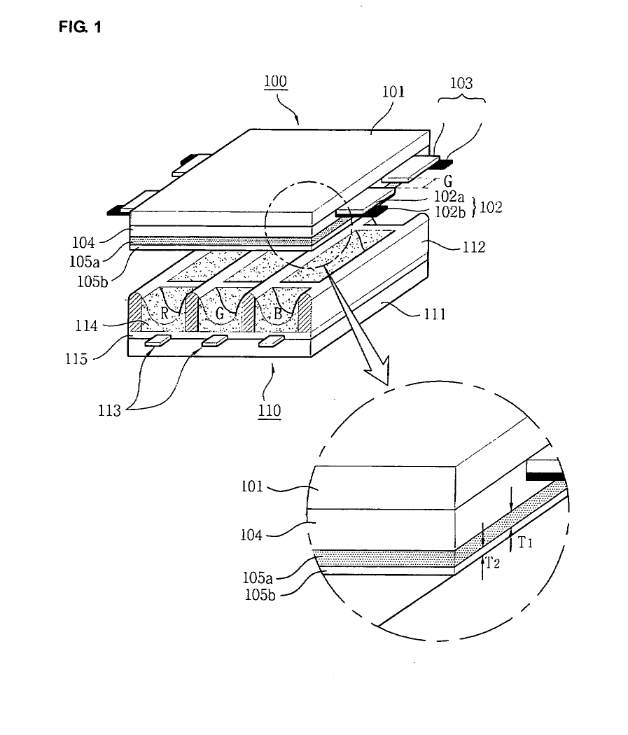

As shown in FIG. 1, the plasma display panel according to the embodiment includes a front panel 100 and a rear panel 110. The front panel 100 includes a front substrate on which a scan electrode 102 and a sustain electrode are displaced. The rear panel 110 includes a rear substrate 111 on which an address electrode 113 is displaced. The address electrode 113 crosses the scan electrode 102 and the sustain electrode 103.

Each of the scan electrode 102 and the sustain electrode 103 includes a transparent electrode 102a and 103a, a bus electrode 102b, 103b. An upper dielectric layer 104 covers the scan electrotrode 102 and the sustain electrode 103, limits a discharge current and insulates the scan electrode 102 and the sustain electrode 103. A first protective layer 105a and a second protective layer 105b are displaced on the upper dielectric layer 304, and are formed through a deposition of magnesium oxide(MgO). The first protective layer 105a covers the upper dielectric layer 104, and the second protective layer covers the first protective layer 105a, and has an area less than an area of the first protective layer 105a.

The first protective layer 105a includes a dopant for increasing a secondary electron emission coefficient. A concentration of the dopant may range from 100 ppm to 1000 ppm. When the concentration of the dopant ranges from 100 ppm to 1000 ppm, a secondary electron is emitted easily, and a stable discharge characteristic and a jitter characteristic can be sustained. The first protective layer 105a includes at least one of Si or Ti. Namely, the dopant of the first protective layer 105a is at least one of Si or Ti.

In the embodiment, a thickness Ti of the first protective layer 105a may be different from a thickness T2 of the second protective layer 105b. And the thickness T1 of the first protective layer 105a may be greater than the thickness T2 of the second protective layer 105b. Since the thickness T1 of the first protective layer 105a is greater than the thickness T2 of the second protective layer 105b, the first protective layer 105a protects the upper dielectric layer 104 better than the second protective layer 105b.

The thickness T2 of the second protective layer 105b may range from 50 □ to 1000 □. When the thickness T2 of the second protective layer 105b ranges from 50 □ to 1000 □, a removal of the second protective layer 105b by a collision of a positive ion is facilitated during an aging process. The thickness T2 of the second protective layer 105b may range from 50 □ to 100□. When the thickness T2 of the second protective layer 105b ranges from 50 □ to 100 □, a time for the aging process decreases.

A portion of the second protective layer 105b removed during the aging process is a protion corresponding to the scan electrode 102 and the sustain electrode. A region of the second protective layer 105b after the aging process may include at least one of a region corresponding to a gap G between the scan electrode 102 and the sustain electrode 103, or a region corresponding to the barrier rib 112.

The gap G between the scan electrode 102 and the sustain electrode 103 may be a distance between the transparent electrode 102a of the scan electrode 102 and the transparent electrode 103a of the sustain electrode 103. In case that each of the scan electrode 102 and the sustain electrode 103 includes only a bus electrode 102b, 103b, the gap G between the scan electrode 102 and the sustain electrode 103 may be a distance between the bus electrode 102b of the scan electrode 102 and the bus electrode 103b of the sustain electrode 103.

The protective layer 105a protects the upper dielectric layer 104 and facilitates an emission of the secondary electrons. Namely, the popant of the first protective layer 105a increases a conductivity and a secondary electron emission coefficient of the first protective layer 105a.

The second protective layer may not include a dopant, or may include the dopant of a concentration less than the concentration of the first protective layer 105a. The conductivity and the secondary electron emission coefficient of the first protective layer 105a is greater than the conductivity and the secondary electron emission coefficient of the second protective layer 105b. Accordingly, the second protective layer 105b obstructs a move of charges between discharge cells.

Namely, the first protective layer 105a facilitates an emission of the secondary electron, and sustains an improved discharge characteristic by an obstruction of the move of the charges. Specially, although a temperature varies, the first protective layer 105a obstructs of the move of the charges and the discharge characteristic of the plasma display panel according to the embodiment, is sustained. For example, because the first protective layer 105a facilitates the emission of the secondary electron, a discharge firing voltage decreases, and a jitter characteristic improves. Because the second protective layer 105b obstructs the move of the charges between discharge cells, the discharge firing voltage and the jitter characteristic is sustained irrespective of a variety of a temperature.

The rear panel 110 Of FIG. 1 includes a bottom dielectric layer 115. The bottom dielectric layer 115 covers the address electrode 115, and insulates the address electrodes 115. The barrier rib 112 is displaced on the bottom dielectric layer 115, and partitions discharge cells. A phosphor 114 is displaced between the barrier ribs.

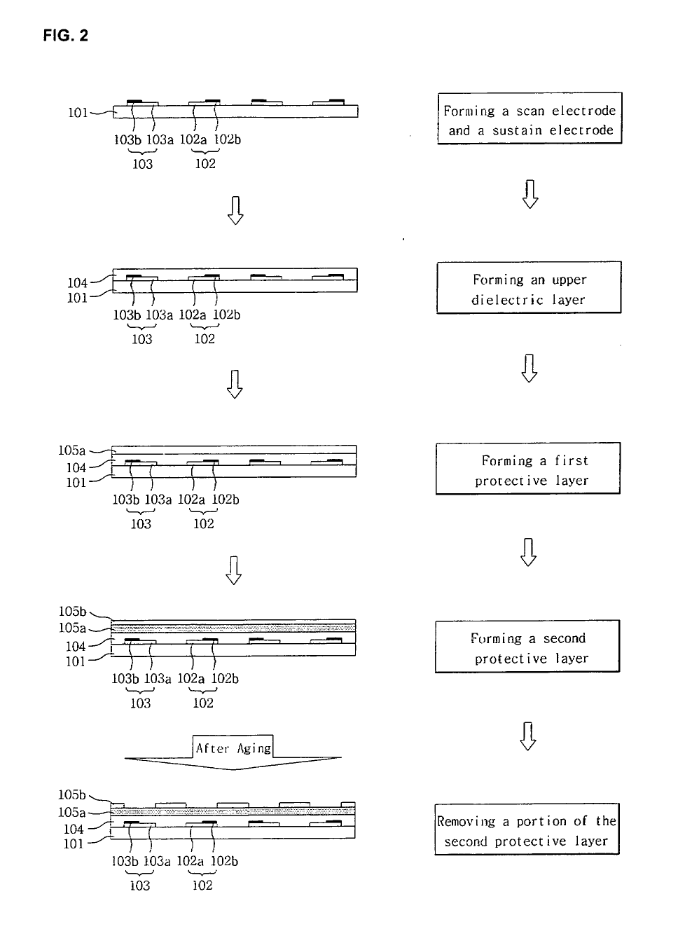

As illustrated in FIG. 2, the scan electrode 102 and the sustain electrode 103 including the transparent electrode 102a, 103a and the bus electrode 102b, 103b are formed on the front substrate 101.

The upper dielectric layer 104 is formed on the scan electrode 102 and the sustain electrode 103, and insulates the scan electrode 102 and the sustain electrode 103.

The first protective layer 105a is formed on the upper dielectric layer 104 through deposition of a protective material such as magnesium oxide doped with a dopant. The dopant may include at least one of Si or Ti. The concentration of the dopant may range from 100 ppm to 1000 ppm.

The second protective layer 105b is formed on the first protective layer 105a through deposition of a protective material such as magnesium oxide. A thickness of the first protective layer 105a may be greater than a thickness of the second protective layer 105b. The thickness of the second layer 105b may range from 50 □ to 1000 □, or from 50 □ to 100 □.

Only the front panel 100 is illustrated in FIG. 2. The front panel 100 is coalescent with a rear panel (not shown), and then an aging process is performed. During the aging process, an aging pulse is alternately supplied to the scan electrode 102 and the sustain electrode 103, and A portion of the second protective layer 105a is removed through collision of positive ions with the second protective layer 105b. When the aging pulse is supplied, the positive ions move between the scan electrode 102 and the sustain electrode 103, and a region of the second protective layer 105b corresponding to the scan electrode 102 and the sustain electrode 103 is removed. A region of the remained second protective layer 105b may include at least one of a region corresponding to a gap between the scan electrode and the sustain electrode or a region corresponding to the barrier rib.

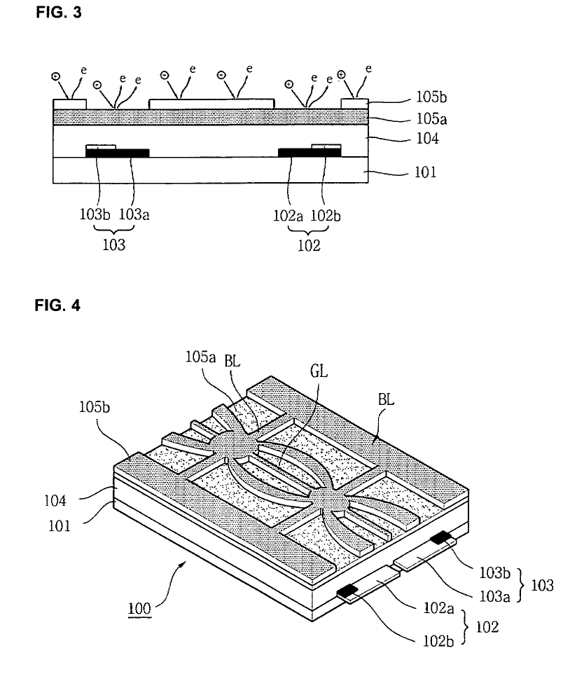

As shown in FIG. 3, because the first protective layer 105a includes a podant, a secondary electron emission coefficient of the first protective layer 105a is greater than a secondary electron emission coefficient of the second protective layer 105b. When the first protective layer 105a doped with the popant is formed, excess electrons and excess holes are generated, and a lot of second electrons emit from the first protective layer 105a by a collision of charges. The number of the second electrons emitted from the first protective layer 105a is greater than the number of the second electrons emitted from the second protective layer 105b, and the secondary electron emission coefficient of the first protective layer 105a is greater than the secondary electron emission coefficient of the second protective layer 105b.

Because the second protective layer 105b is not doped, or has a doping concentration of the second protective layer 105b less than a doping concentration of the first protective layer 105b, the second protective layer 105b has an Orientation, Crystalline Quality, and a film density superior to them of the first protective layer 105a.

As shown in FIG. 4, because a region of the second protective layer 105b corresponding to the scan electrode 102 and the sustain electrode is removed, at least one of a region GL of the second protective layer 105b corresponding to a gap between the scan electrode 102 and the sustain electrode 103 or a region BL of the second protective layer 105b corresponding to a barrier rib, is remained. Because a conductivity of the remained second protective layer 105b is less than a conductivity of the first protective layer 105a, the remained second protective layer 105b obstructs a move of charges in a discharge cell to an adjacent discharge cell. Accordingly, a stable discharge is generated.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such limitation is not intended to be interpreted under 35 USC 112(6).

What is claimed is:

1. A plasma display panel comprising:
a barrier rib;
a substrate on which a scan electrode and a sustain electrode are displaced;
a dielectric layer covering the scan electrode and the sustain electrode;
a first protective layer covering the dielectric layer; and
a second protective layer covering the first protective layer, and having an area less than an area of the first protective layer.

2. The plasma display panel of claim 1, wherein
a region of the second protective layer includes at least one of a region corresponding to a gap between the scan electrode and the sustain electrode or a region corresponding to the barrier rib.

3. The plasma display panel of claim 1, wherein
the first protective layer includes a dopant.

4. The plasma display panel of claim 1, wherein
the first protective layer includes a dopant, and a concentration of the dopant ranges from 100 ppm to 1000 ppm.

5. The plasma display panel of claim 1, wherein
each of the scan electrode and the sustain electrode includes a transparent electrode and a bus electrode, and
a portion of the first protective layer is positioned at a region corresponding to a gap between the transparent electrode of the scan eletrode and the transparent electrode of the sustain electrode.

6. The plasma display panel of claim 1, wherein
a conductivity of the first protective layer is greater than a conductivity of the second protective layer.

7. The plasma display panel of claim 1, wherein
a thickness of the first protective layer is greater than a thickness of the second protective layer.

8. The plasma display panel of claim 1, wherein
a thickness of the second protective layer ranges from 50 to 1000.

9. The plasma display panel of claim 1, wherein
a thickness of the second protective layer ranges from 50 to 100.

10. The plasma display panel of claim 1, wherein
the first protective layer includes at least one of Si or Ti.

11. The plasma display panel of claim 1, wherein
the first protective layer and the second protective layer include MgO.

12. The plasma display panel of claim 1, wherein
a secondary electron emission coefficient of the first protective layer is greater than a secondary electron emission coefficient of the second protectiver layer.

13. A manufacturing method of a plasma display panel including a barrier rib, comprising:
forming a scan electrode and a sustain electrode on a substrate;
forming a dielectric layer covering the scan electrode and the sustain electrode;
forming a first protective layer on the dielectric layer;
forming a second protective layer on the first protective layer; and
removing a portion of the second layer.

14. The manufacturing method of claim 13, wherein
a region of the second protective layer includes at least one of a region corresponding to a gap between the scan electrode and the sustain electrode or a region corresponding to the barrier rib.

15. The manufacturing method of claim 13, wherein
the first protective layer includes a dopant.

16. The manufacturing method of claim 13, wherein
the first protective layer includes a dopant, and a concentration of the dopant ranges from 100 ppm to 1000 ppm.

17. The manufacturing method of claim 13, wherein
each of the scan electrode and the sustain electrode includes a transparent electrode and a bus electrode, and
a portion of the first protective layer is positioned at a region corresponding to a gap between the transparent electrode of the scan eletrode and the transparent electrode of the sustain electrode.

18. The manufacturing method of claim 13, wherein
a conductivity of the first protective layer is greater than a conductivity of the second protective layer.

19. The manufacturing method of claim 13, wherein
a thickness of the first protective layer is greater than a thickness of the second protective layer.

20. The manufacturing method of claim 13, wherein
a thickness of the second protective layer ranges from 50 to 1000.

21. The manufacturing method of claim 13, wherein
a thickness of the second protective layer ranges from 50 to 100.

22. The manufacturing method of claim 13, wherein
the first protective layer includes at least one of Si or Ti.

23. The manufacturing method of claim 13, wherein
a portion of the second protective layer is removed by a supply of an aging pulse to the scan electrode and the sustain electrode alternately.

24. The manufacturing method of claim 13, wherein
a secondary electron emission coefficient of the first protective layer is greater than a secondary electron emission coefficient of the second protectiver layer.
